(19) United States
(12) Patent Application Publication
(10) Pub. No.: US 2025/0330755 A1
(43) Pub. Date: Oct. 23, 2025

(54) PIEZOELECTRIC DEVICE

(71) Applicants: DENSO CORPORATION, Kariya-city (JP); TOYOTA JIDOSHA KABUSHIKI KAISHA, Toyota-shi (JP); MIRISE Technologies Corporation, Nisshin-shi (JP); Nisshinbo Micro Devices Inc., Tokyo (JP)

(72) Inventors: Yuya SAKURAI, Nisshin-shi (JP); Hideo YAMADA, Nisshin-shi (JP); Takahide USUI, Fujimino-shi (JP)

(21) Appl. No.: 19/172,377

(22) Filed: Apr. 7, 2025

(30) Foreign Application Priority Data
Apr. 19, 2024 (JP) 2024-068567

(51) Int. Cl. H04R 17/02; H10N 30/50

(52) U.S. Cl. CPC H04R 17/02; H10N 30/503

(57) ABSTRACT

A piezoelectric device includes a beam portion that has a plate shape perpendicular to an axial direction of a directional axis, and has a fixed end provided on one side in a first direction perpendicular to the axial direction, a free end provided on an opposite side in the first direction, one surface provided on one side in the axial direction, and an opposite surface provided on an opposite side in the axial direction. The beam portion includes a concave and convex structure portion having a concave and a convex one of which is provided on the one surface and the other is provided on the opposite surface so as to overlap each other in the axial direction. The concave and the convex extend linearly in a second direction perpendicular to the axial direction and the first direction.

### CROSS REFERENCE TO RELATED APPLICATION

The present application claims the benefit of priority from Japanese Patent Application No. 2024-068567 filed on Apr. 19, 2024. The entire disclosure of the above application is incorporated herein by reference.

### TECHNICAL FIELD

The present disclosure relates to a piezoelectric device that can be adopted for a microphone or a speaker.

### BACKGROUND

A piezoelectric MEMS microphone having a cantilever structure includes a beam portion that is supported in a cantilever manner, formed in a plate shape, and has a piezoelectric layer. The beam portion vibrates upon receiving sound waves or ultrasonic waves. The vibration of the beam portion is then converted into an electrical signal. The MEMS is an abbreviation for Micro Electro Mechanical Systems.

### SUMMARY

A piezoelectric device according to one example of the present disclosure includes a beam portion and a support portion. The beam portion includes a piezoelectric layer made of a piezoelectric material, has a plate shape perpendicular to an axial direction of a directional axis of the piezoelectric device, and has a fixed end provided on one side of the beam portion in a first direction perpendicular to the axial direction, a free end provided on an opposite side of the beam portion in the first direction, one surface provided on one side of the beam portion in the axial direction, and an opposite surface provided on an opposite side of the beam portion in the axial direction. The beam portion is configured as a cantilever beam in which the free end is capable of reciprocating displacement in the axial direction with respect to the fixed end. The fixed end of the beam portion is fixed to the support portion, and the support portion supports the fixed end. The beam portion includes a concave and convex structure portion having at least one of a first concave and convex part and a second concave and convex part. The first concave and convex part has a first concave provided on the one surface and extending linearly in a second direction perpendicular to the axial direction and the first direction, and a first convex provided on the opposite surface at a portion overlapping the first concave on the opposite side in the axial direction and extending linearly in the second direction. The second concave and convex part has a second convex provided on the one surface and extending linearly in the second direction, and a second concave provided on the opposite surface at a portion overlapping the second convex on the opposite side in the axial direction and extending linearly in the second direction.

### BRIEF DESCRIPTION OF DRAWINGS

Objects, features and advantages of the present disclosure will become apparent from the following detailed description made with reference to the accompanying drawings. In the drawings:

FIG. 1 is a plan view illustrating a piezoelectric device according to a first embodiment;

FIG. 2 is an enlarged perspective view of a portion II of FIG. 1 and is also a diagram schematically illustrating a vibration plate and the vicinity thereof in the piezoelectric device according to the first embodiment;

FIG. 3 is a diagram schematically illustrating a cross section of the piezoelectric device taken along line III-III of FIG. 2;

FIG. 4A is a diagram schematically illustrating a part of a cross section of a beam portion taken along line III-III of FIG. 2 in a comparative example;

FIG. 4B is a diagram schematically illustrating a part of a cross section of a beam portion taken along line III-III of FIG. 2 in the first embodiment;

FIG. 5A is a diagram schematically illustrating a part of a cross section of the beam portion taken along line V-V of FIG. 2 in the comparative example;

FIG. 5B is a diagram schematically illustrating a part of a cross section of the beam portion taken along line V-V of FIG. 2 in the first embodiment;

FIG. 6 is a perspective view similar to FIG. 2, in which a plurality of concave and convex structure portions included in the beam portion in the vibration plate are shown by dashed lines in a simplified illustration;

FIG. 7 is a diagram schematically illustrating a cross section taken along line VII-VII of FIG. 6, and is also a diagram schematically illustrating an enlarged cross section of a portion VIIa of FIG. 3 in the first embodiment;

FIG. 8 is a diagram schematically illustrating a cross section taken along line VIII-VIII of FIG. 6, and is also a diagram schematically illustrating an enlarged cross section of a portion VIIIa of FIG. 3 in the first embodiment;

FIG. 9 is a diagram schematically illustrating a cross section taken along line IX-IX of FIG. 6, and is also a diagram schematically illustrating an enlarged cross section of a portion IXa of FIG. 3 in the first embodiment;

FIG. 10 is a perspective view of a vibration plate and the vicinity thereof in a piezoelectric device according to a second embodiment in which a plurality of concave and convex structure portions included in a beam portion of the vibration plate are shown by dashed lines in a simplified illustration;

FIG. 11 is a perspective view of a vibration plate and the vicinity thereof in a piezoelectric device according to a third embodiment in which a concave and convex structure portion included in a beam portion of the vibration plate is shown by a dashed line in a simplified illustration;

FIG. 12 is a perspective view of a vibration plate and the vicinity thereof in a piezoelectric device according to a fourth embodiment in which a concave and convex structure portion included in a beam portion of the vibration plate is shown by a dashed line in a simplified illustration; and

FIG. 13 is a diagram schematically illustrating a cross section taken along line XIII-XIII of FIG. 12 and is also a diagram schematically illustrating an enlarged cross section of a portion corresponding to a portion XIIIa of FIG. 3 in the fourth embodiment.

### DETAILED DESCRIPTION

In a piezoelectric MEMS microphone having a cantilever structure, a deflection occurs in a beam portion formed in a plate shape due to a stress distribution in a thickness direction of the beam portion. The deflection of the beam portion occurs not only in a cross section along a beam extension direction extending from a fixed end to a free end of the beam portion and along the thickness direction, but also in a transverse cross section perpendicular to the beam extension direction. In particular, the defection of the beam portion that occurs in the transverse cross section hinders a vibration of the beam portion, resulting in a decrease in a sensitivity of the piezoelectric MEMS microphone.

With regard to the above issue, the stress distribution in the beam portion can be adjusted, for example, by dividing the beam portion of the piezoelectric MEMS microphone into layers in the thickness direction.

However, after detailed investigations by the present inventors, it was found that even if the stress distribution in the beam portion was adjusted using the above-described method, it would be difficult to restrict the deflection of the beam portion due to in-plane variations in stress distribution during a deposition of each layer of the beam portion and variations in stress distribution between lots.

A piezoelectric device according to an aspect of the present disclosure is to be adopted for a microphone or a speaker, and includes a beam portion and a support portion. The beam portion includes a piezoelectric layer made of a piezoelectric material, has a plate shape perpendicular to an axial direction of a directional axis of the piezoelectric device, and has a fixed end provided on one side of the beam portion in a first direction perpendicular to the axial direction, a free end provided on an opposite side of the beam portion in the first direction, one surface provided on one side of the beam portion in the axial direction, and an opposite surface provided on an opposite side of the beam portion in the axial direction. The beam portion is configured as a cantilever beam in which the free end is capable of reciprocating displacement in the axial direction with respect to the fixed end. The fixed end of the beam portion is fixed to the support portion, and the support portion supports the fixed end. The beam portion includes a concave and convex structure portion having at least one of a first concave and convex part and a second concave and convex part. The first concave and convex part has a first concave provided on the one surface and extending linearly in a second direction perpendicular to the axial direction and the first direction, and a first convex provided on the opposite surface at a portion overlapping the first concave on the opposite side in the axial direction and extending linearly in the second direction. The second concave and convex part has a second convex provided on the one surface and extending linearly in the second direction, and a second concave provided on the opposite surface at a portion overlapping the second convex on the opposite side in the axial direction and extending linearly in the second direction.

In a case where the beam portion includes the concave and convex structure portion as described above, a bending rigidity of the beam portion is not increased against a deflection of the beam portion that occurs in a cross section perpendicular to the second direction, but a bending rigidity of the beam portion is increased against a deflection of the beam portion that occurs in a cross section perpendicular to the first direction. Therefore, while not hindering the vibration of the beam portion, the deflection of the beam portion that occurs in the cross section perpendicular to the first direction can be restricted compared to, for example, a case in which there is no concave and convex structure portion and the entire beam portion is flat. Note that the cross section perpendicular to the first direction corresponds to a transverse cross section.

Hereinafter, embodiments are described with reference to the drawings. In the following embodiments, the same or equivalent parts are denoted by the same reference numerals in the drawings.

### First Embodiment

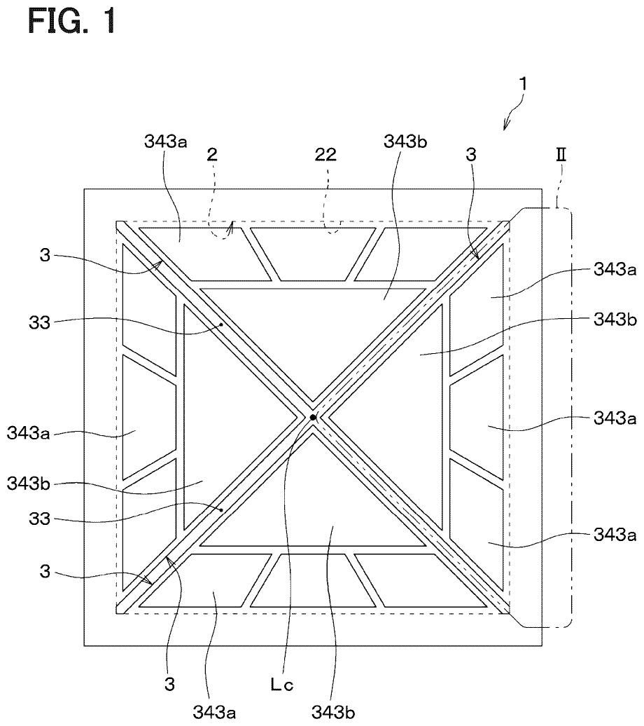

A piezoelectric device 1 according to the present embodiment shown in FIGS. 1 to 3 is an electroacoustic transducer having a configuration of a so-called piezoelectric MEMS microphone. Therefore, the piezoelectric device 1 of the present embodiment is configured to convert sound wave vibrations or ultrasonic vibrations propagated from an external space Sz into electric signals.

In the present embodiment, each component of the piezoelectric device 1 may be described based on a directional axis Lc of the piezoelectric device 1. The directional axis Lc is an imaginary straight line that serves as a reference for the directivity of the piezoelectric device 1 that receives sound waves or ultrasonic waves, and may also be referred to as a “directional central axis”. When a range of directionality (that is, a range in which a specified gain can be obtained) is represented as a three-dimensional shape such as an approximately conical shape or an approximately spindle shape, the directional axis Lc typically corresponds to a virtual straight line indicating an axial center of the three-dimensional shape. Specifically, for example, the directional axis Lc is a central axis of a half-power angle.

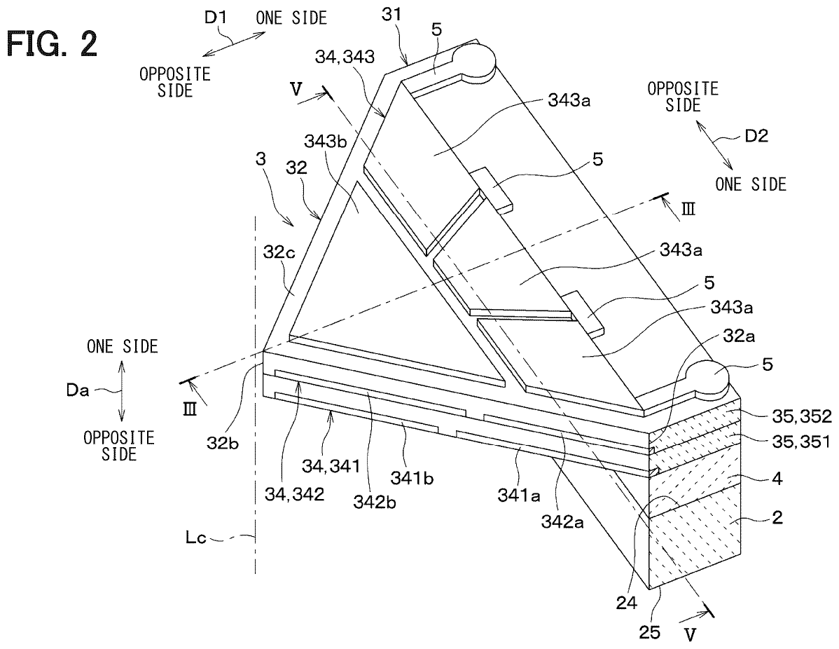

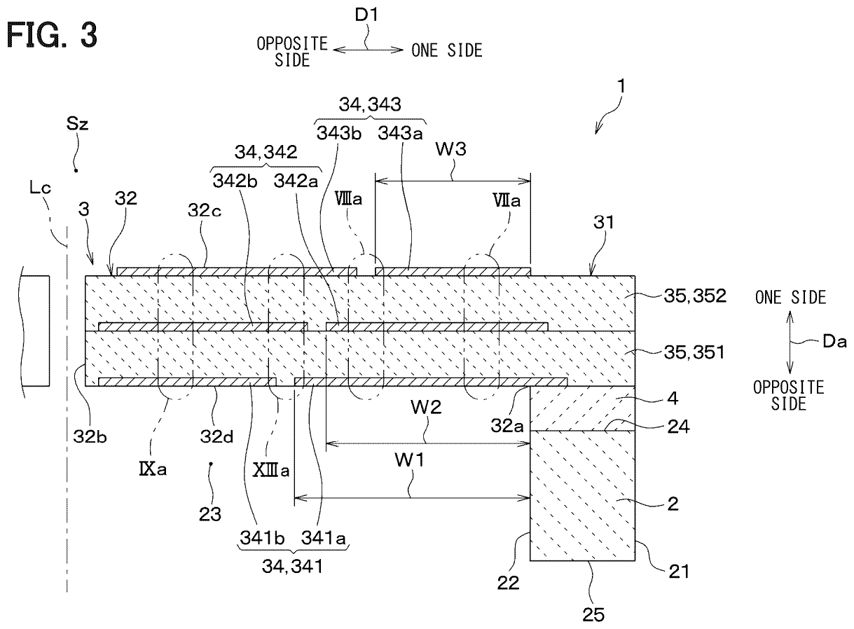

In FIG. 2 and FIG. 3, a directional axis direction Da, which is an axial direction of the directional axis Lc, a first direction D1, and a second direction D2 are each indicated by a double-headed arrow. The directional axis direction Da is parallel to the directional axis Lc. The first direction D1 is perpendicular to the directional axis direction Da, and the second direction D2 is perpendicular to the directional axis direction Da and the first direction D1.

As shown in FIGS. 1 to 3, the piezoelectric device 1 of the present embodiment includes a base substrate 2, a vibration plate 3, an oxide film 4, and a signal wiring 5.

The base substrate 2 functions as a support portion for supporting the vibration plate 3, and is formed in a cylindrical or an annular shape surrounding the directional axis Lc. In the present embodiment, the base substrate 2 has a square cylindrical shape or a square annular shape with the directional axis Lc as the central axis. Moreover, the base substrate 2 is formed so as to have a square outer shape in plan view. The base substrate 2 is made of a ceramic substrate such as alumina, a silicon-based semiconductor substrate, or the like. Note that the plan view means a view in a direction along the directional axis direction Da.

The base substrate 2 has an outer wall surface 21 that is parallel to the directional axis Lc and exposed radially outward from the directional axis Lc, and an inner wall surface 22 that is parallel to the directional axis Lc and surrounds the directional axis Lc. A hollow portion 23 that is a space surrounded by the inner wall surface 22 is formed in a quadrangular prism shape having a square shape in plan view.

The base substrate 2 also has one end surface 24 which is an end surface formed on one side in the directional axis direction Da, and an opposite end surface 25 which is an end surface formed on an opposite side in the directional axis direction Da. The one end surface 24 and the opposite end surface 25 are formed in a flat plane shape with the directional axis direction Da as the normal direction. The one end surface 24 is joined to the vibration plate 3 via an insulating oxide film 4. The oxide film 4 is disposed between the base substrate 2 and a fixed portion 31 of the vibration plate 3 in the directional axis direction Da. For example, the oxide film 4 is made of tetra ethoxy silane (TEOS) or the like.

The vibration plate 3 is formed in a thin plate shape having a thickness in the directional axis direction Da. In other words, the vibration plate 3 is formed in a plate shape perpendicular to the directional axis direction Da, that is, in a plate shape extending in the first direction D1 and the second direction D2. Focusing on the roles of each portion of the vibration plate 3, the vibration plate 3 includes the fixed portion 31 and a beam portion 32.

The fixed portion 31 of the vibration plate 3 is joined to the one end surface 24 of the base substrate 2 via the oxide film 4, and is thereby fixed to the base substrate 2. Therefore, the base substrate 2 is disposed on the opposite side in the directional axis direction Da with respect to the fixed portion 31 and the beam portion 32 of the vibration plate 3.

The beam portion 32 of the vibration plate 3 is formed so as to extend from the fixed portion 31 toward the directional axis Lc along the first direction D1. Since the vibration plate 3 is formed in the plate shape perpendicular to the directional axis direction Da as described above, the beam portion 32 is also formed in a plate shape perpendicular to the directional axis direction Da.

The beam portion 32 is formed so as to overlap one side of the hollow portion 23 in the directional axis direction Da. In other words, the beam portion 32 constitutes a portion of the vibration plate 3 located closer to the directional axis Lc than the inner wall surface 22 of the base substrate 2. Therefore, the beam portion 32 faces the hollow portion 23 from the one side in the directional axis direction Da. The beam portion 32 is configured to flexibly vibrate in such a manner that an antinode of the vibration moves along the directional axis Lc. That is, the beam portion 32 has a fixed end 32a and a free end 32b.

The fixed end 32a is located at one end of the beam portion 32 disposed on one side in the first direction D1. The fixed end 32a is a portion that constitutes a node of the vibration in the beam portion 32, and is provided at a position that overlaps with the inner wall surface 22 of the base substrate 2 in plan view. In contrast, the free end 32b is located at the other end of the beam portion 32 provided on the opposite side in the first direction D1. The free end 32b is a portion that constitutes an antinode of the vibration in the beam portion 32, and is provided at a position close to the directional axis Lc.

The fixed end 32a is fixed to the base substrate 2 via the fixed portion 31 of the vibration plate 3 and the oxide film 4, and the base substrate 2 supports the fixed end 32a. In other words, the base substrate 2 supports the beam portion 32 at the fixed end 32a. Therefore, the beam portion 32 of the vibration plate 3 is configured as a cantilever beam with the free end 32b capable of reciprocating displacement in the directional axis direction Da with respect to the fixed end 32a. That is, the beam portion 32 is provided so as to be capable of vibrating in such a manner that the free end 32b reciprocates along the directional axis Lc while the fixed end 32a is fixedly supported by the base substrate 2.

The beam portion 32 of the vibration plate 3 has one surface 32c on the one side in the directional axis direction Da, and an opposite surface 32d on the opposite side in the directional axis direction Da. Each of the one surface 32c and the opposite surface 32d of the beam portion 32 is formed so as to extend in the first direction D1 and the second direction D2 with the directional axis direction Da as the normal direction.

In the present embodiment the beam portion 32 of the vibration plate 3 has, in plan view, an approximately isosceles right triangle shape, with the fixed end 32a forming the base and the free end 32b forming the apex, so as to correspond to the square outer shape of the base substrate 2 in plan view. Therefore, the beam portion 32 is formed so that the width in the second direction D2 increases from the free end 32b toward the fixed end 32a. In other words, the beam portion 32 is formed so as to increase in width in the second direction D2 toward the one side in the first direction D1.

As shown in FIG. 1, the piezoelectric device 1 of the present embodiment has four vibration plates 3 having the above-described configuration. The four vibration plates 3 are positioned at equal intervals (specifically, 90 degree intervals) in the circumferential direction around the directional axis Lc, with the free ends 32b facing the directional axis Lc in plan view. That is, for any of the four vibration plates 3, the opposite side in the first direction D1 is a side close to the directional axis Lc.

The beam portions 32 of the plurality of vibration plates 3 are divided by a slit 33 so as to be spaced apart in the circumferential direction of the directional axis Lc. Therefore, the slit 33 penetrates between the beam portions 32 in the directional axis direction Da, and are formed in a substantially X-shape that corresponds to the diagonal lines of the square shape of the hollow portion 23 in plan view. Since the plurality of vibration plates 3 of the piezoelectric device 1 of the present embodiment all have the same configuration, the vibration plates 3 will be described by focusing on one of the plurality of vibration plates 3.

As shown in FIG. 2 and FIG. 3, the vibration plate 3 has a multi-layer structure. Focusing on the multi-layer structure of the vibration plate 3, the vibration plate 3 includes a first electrode layer 341, a second electrode layer 342, a third electrode layer 343, a first piezoelectric layer 351, and a second piezoelectric layer 352. For example, the first piezoelectric layers 351, the second piezoelectric layer 352, the first electrode layers 341, and the second electrode layers 342 extend in both the fixed portion 31 and the beam portion 32 of the vibration plate 3, and the third electrode layer 343 extends in the beam portion 32.

In the description of the present embodiment, when the first electrode layer 341, the second electrode layer 342, and the third electrode layer 343 are referred to collectively without distinction, they may be referred to as electrode layers 34. When the first piezoelectric layer 351 and the second piezoelectric layer 352 are referred to collectively without distinction, they may be referred to as piezoelectric layers 35.

The electrode layer 34 is made of a conductive material such as a molybdenum film, an amorphous molybdenum film, or a polycrystalline silicon film. The piezoelectric layer 35 is made of a piezoelectric material. Examples of the piezoelectric material that may be used to form the piezoelectric layer 35 include AlN (that is, aluminum nitride), ScAlN (that is, scandium aluminum nitride), ZnO (that is, zinc oxide), PZT, KLN, KNN, and BaTiO₃ (that is, barium titanate). The PZT stands for lead zirconate titanate, the KLN stands for potassium lithium niobate, that is, K₃Li₂Nb₅O₁₅, and the KNN stands for potassium sodium niobate that is, (K,Na)NbO₃.

In addition, the plurality of electrode layers 34 and the plurality of piezoelectric layers 35 are laminated in the directional axis direction Da in the order of the first electrode layer 341, the first piezoelectric layer 351, the second electrode layer 342, the second piezoelectric layer 352, and the third electrode layer 343 from the opposite side in the directional axis direction Da. In short, the plurality of electrode layers 34 and the plurality of piezoelectric layers 35 are alternately laminated in the directional axis direction Da, so that each of the plurality of piezoelectric layers 35 is sandwiched between a pair of electrode layers 34. In other words, the plurality of electrode layers 34 each constitute a different layer of the beam portion 32 of the vibration plate 3 that is separated from each other by the piezoelectric layer 35.

The first electrode layer 341 is laminated and joined to the one side of the oxide film 4 in the directional axis direction Da, and forms the opposite surface 32d of the beam portion 32. In contrast, the third electrode layer 343 forms the one surface 32c of the beam portion 32. The first piezoelectric layer 351 is partially not covered by the first electrode layer 341, and therefore the first piezoelectric layer 351 is joined to a portion of the oxide film 4 without the first electrode layer 341 therebetween, and forms a portion of the opposite surface 32d of the beam portion 32. Furthermore, the second piezoelectric layer 352 is partially not covered by the third electrode layer 343, and therefore the second piezoelectric layer 352 forms a portion of the one surface 32c of the beam portion 32.

The first electrode layer 341 includes a first sensor electrode 341a and a first floating electrode 341b. Similarly, the second electrode layer 342 includes a second sensor electrode 342a and a second floating electrode 342b, and the third electrode layer 343 includes a third sensor electrode 343a and a third floating electrode 343b. The first to third sensor electrodes 341a, 342a, 343a are electrodes for outputting an electrical signal corresponding to the bending vibration of the beam portion 32, and are therefore electrically connected to the signal wiring 5, which is a wiring leading to the outside of the piezoelectric device 1. On the other hand, the first to third floating electrodes 341b, 342b, and 343b are disposed away from the signal wiring 5 and are electrically insulated.

The first to third sensor electrodes 341a, 342a, 343a are positioned on the base side of the cantilever structure of the beam portion 32 of the vibration plate 3, and the first to third floating electrodes 341b, 342b, 343b are positioned on the tip side of the cantilever structure. In detail, in the first electrode layer 341, the first floating electrode 341b is positioned on the opposite side in the first direction D1 with respect to the first sensor electrode 341a, and in the second electrode layer 342, the second floating electrode 342b is positioned on the opposite side in the first direction D1 with respect to the second sensor electrode 342a. In the third electrode layer 343, the third floating electrode 343b is disposed on the opposite side in the first direction D1 with respect to the third sensor electrode 343a.

Furthermore, since there is a small gap between the first sensor electrode 341a and the first floating electrode 341b, the first floating electrode 341b is separated from the first sensor electrode 341a. Similarly, since there is a small gap between the second sensor electrode 342a and the second floating electrode 342b, the second floating electrode 342b is separated from the second sensor electrode 342a. Furthermore, since there is also a small gap between the third sensor electrode 343a and the third floating electrode 343b, the third floating electrode 343b is separated from the third sensor electrode 343a. As a result, electrical continuity between the first to third sensor electrodes 341a, 342a, 343a and the first to third floating electrodes 341b, 342b, 343b, respectively, is cut off.

In addition, the gap between the first sensor electrode 341a and the first floating electrode 341b, the gap between the second sensor electrode 342a and the second floating electrode 342b, and the gap between the third sensor electrode 343a and the third floating electrode 343b each extend linearly along the second direction D2. The gaps between the sensor electrodes 341a, 342a, 343a and the floating electrodes 341b, 342b, 343b, that is, electrode gaps, are formed by removing portions of respective electrode layers 34 by etching or the like. The first piezoelectric layer 351 is disposed in the electrode gap between the first sensor electrode 341a and the first floating electrode 341b, and the second piezoelectric layer 352 is disposed in the electrode gap between the second sensor electrode 342a and the second floating electrode 342b.

The first to third sensor electrodes 341a, 342a, 343a are formed such that all of the sensor electrodes 341a, 342a, 343a overlap each other in plan view. The positions of the electrode gaps provided in the first to third electrode layers 341, 342, and 343 may be aligned with one another in the first direction D1, but in the present embodiment, they are offset from one another in the first direction D1.

Next, an overview of the operation of the piezoelectric device 1 according to the present embodiment configured as described above will be described. The piezoelectric device 1 according to the present embodiment has a conversion function between the strain caused by bending deformation when the free end 32b of the beam portion 32 moves in the directional axis direction Da, and the voltage between a pair of electrode layers 34 provided on both sides of the piezoelectric layer 35. That is, for example, flexural vibration of the beam portion 32 due to reception of sound waves or ultrasonic waves is extracted as an inter-electrode voltage between the first sensor electrode 341a and the second sensor electrode 342a, and an inter-electrode voltage between the second sensor electrode 342a and the third sensor electrode 343a. These inter-electrode voltages are subjected to signal processing by a signal processing circuit such as an amplifier circuit (not shown), whereby an output signal corresponding to the sound waves or the ultrasonic waves received by the piezoelectric device 1 is generated.

Here, assuming a case in which the beam portion 32 of the vibration plate 3 warps, causing a deflection in a transverse cross section perpendicular to the first direction D1 (for example, a cross section taken along line V-V in FIG. 2). When such a transverse cross-sectional deflection occurs in the beam portion 32, the vibration of the cantilever-shaped beam portion 32 that causes the free end 32b to reciprocate in the directional axis direction Da is hindered, resulting in a decrease in the sensitivity of the piezoelectric device 1 functioning as a microphone.

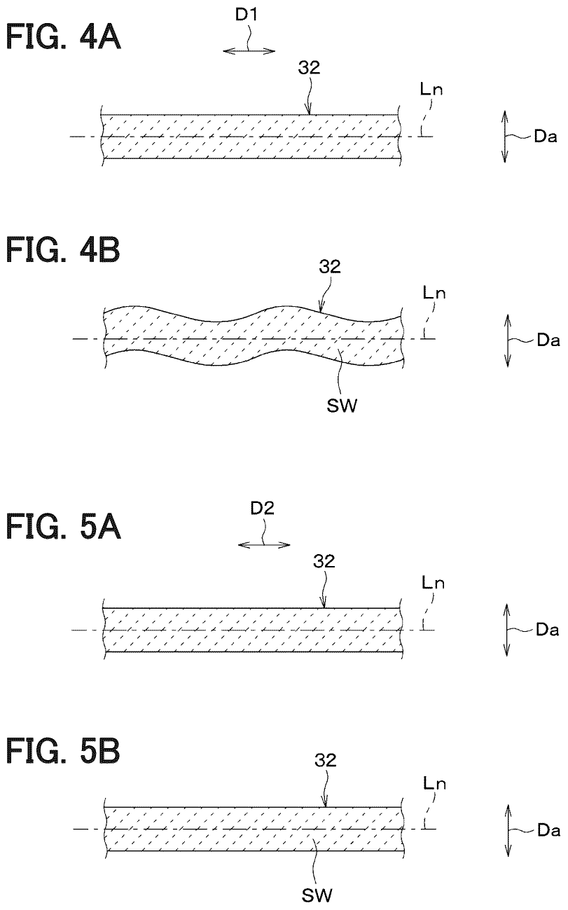

Therefore, the present inventors considered changing a part of the beam portion 32 from the flat plate shape shown in a comparative example of FIG. 4A and FIG. 5A to a wavy structure SW shown in FIG. 4B and FIG. 5B. The wavy structure SW is formed in a wavy shape as shown in FIG. 4B in a cross section perpendicular to the second direction D2 (for example, a cross section taken along line III-III in FIG. 2), and extends linearly along the second direction D2 as shown in FIG. 5B. That is, the wavy structure SW extends along the second direction D2 while maintaining the wavy cross section shown in FIG. 4B.

When such a wavy structure SW is provided in the beam portion 32, the second moment of area of the beam portion 32 with respect to a neutral axis Ln of the bending deformation of the beam portion 32 becomes larger in the cross section perpendicular to the second direction D2 compared to the comparative example in which the entire beam portion is flat, as shown in FIG. 4A and FIG. 4B. On the other hand, in the transverse cross section perpendicular to the first direction D1, the second moment of area does not change whether the wavy structure SW is provided in the beam portion 32 or the entire beam portion 32 is flat, as shown in FIG. 5A and FIG. 5B.

From these facts, the present inventors considered that the wavy structure SW has the effect of countering the above-described transverse cross-sectional deflection of the beam portion 32 and restricting the transverse cross-sectional deflection without hindering the vibration of the beam portion 32 that reciprocates and displaces the free end 32b in the directional axis direction Da. In the present embodiment, the beam portion 32 of the vibration plate 3 is configured taking into consideration the above-described effect of the wavy structure SW.

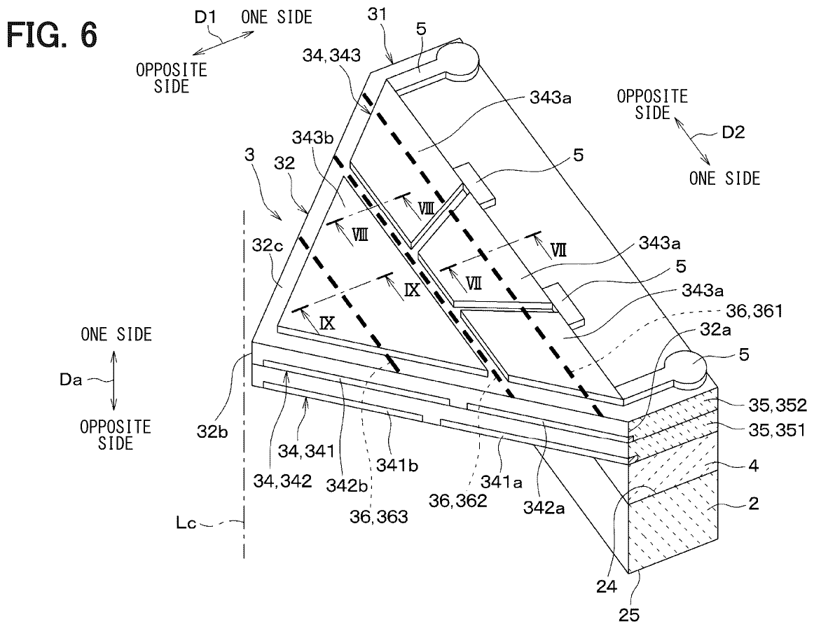

Specifically, as shown in FIGS. 6 to 9, the beam portion 32 of the vibration plate 3 has a first concave and convex structure portion 361, a second concave and convex structure portion 362, and a third concave and convex structure portion 363 which correspond to the above-described wave structure SW. Each of the first concave and convex structure portions 361, the second concave and convex structure portions 362, and the third concave and convex structure portions 363 has a shape that extends linearly in the second direction D2, and extends from one edge to an opposite edge of the beam portion 32 in the second direction D2. The first concave and convex structure portions 361, the second concave and convex structure portions 362, and the third concave and convex structure portions 363 are positioned in parallel to one another at intervals from the one side in the first direction D1 in the order of the first concave and convex structure portion 361, the second concave and convex structure portion 362, and the third concave and convex structure portion 363.

In the description of the present embodiment, when the first concave and convex structure portion 361, the second concave and convex structure portion 362, and the third concave and convex structure portion 363 are collectively referred to without distinction, they may be referred to as concave and convex structure portions 36. In FIG. 6, the illustrations of the concave and convex structure portions 36 are simplified, and each of the concave and convex structure portions 36 is represented by a dashed line. The method of showing the concave and convex structure portions 36 by the dashed lines is also adopted in later-described drawings corresponding to FIG. 6.

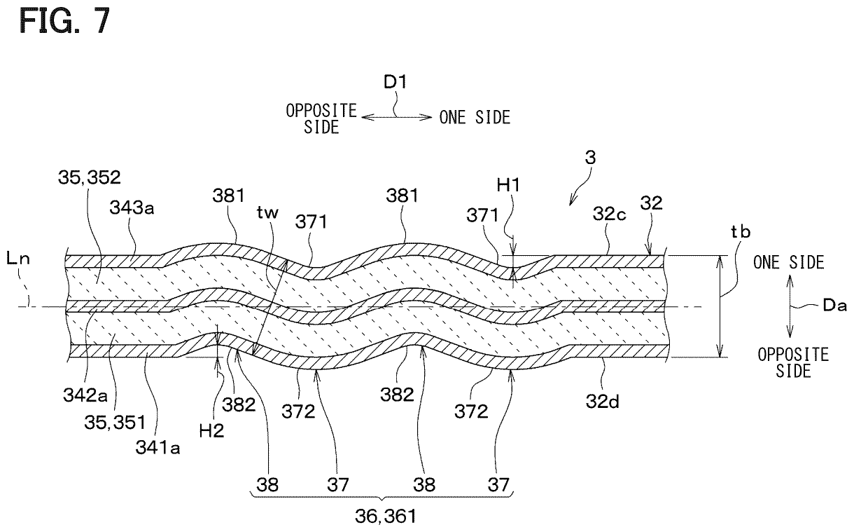

As shown in FIGS. 6 and 7, the first concave and convex structure portion 361 is positioned so that the position of the first concave and convex structure portion 361 in the first direction D1 overlaps with all of the sensor electrodes 341a, 342a, 343a of the beam portion 32. In other words, the first concave and convex structure portion 361 is disposed within a first sensor electrode range W1, a second sensor electrode range W2, and a third sensor electrode range W3 of the beam portion 32 in FIG. 3. The first sensor electrode range W1 is a range occupied by the first sensor electrode 341a in the first direction D1, the second sensor electrode range W2 is a range occupied by the second sensor electrode 342a in the first direction D1, and the third sensor electrode range W3 is a range occupied by the third sensor electrode 343a in the first direction D1. In short, the first concave and convex structure portion 361 is disposed within an overlapping range of the beam portion 32 where the sensor electrode ranges W1, W2, W3 of the sensor electrodes 341a, 342a, 343a all overlap. In the present embodiment, the overlapping range coincides with the third sensor electrode range W3 as shown in FIG. 3.

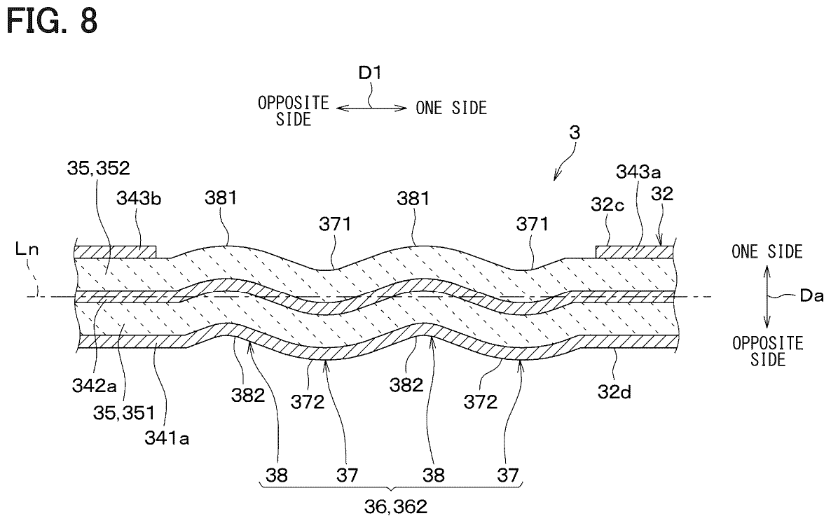

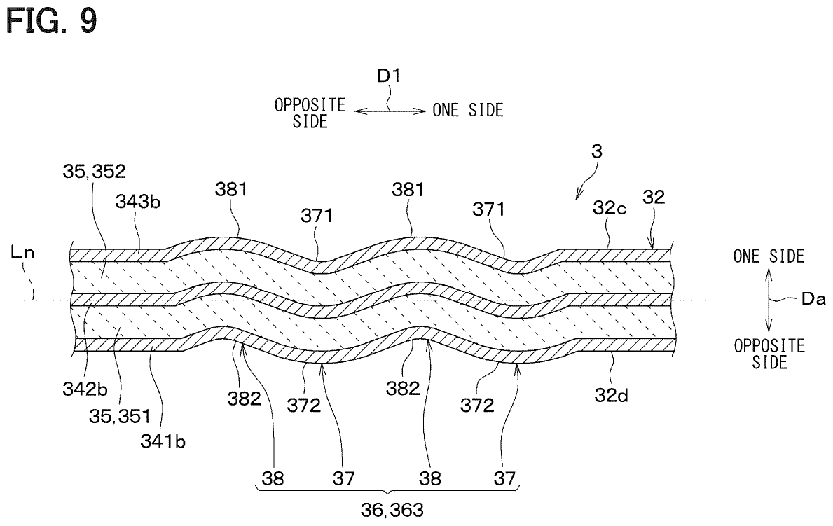

As shown in FIG. 6 and FIG. 8, the second concave and convex structure portion 362 is positioned in the beam portion 32 between the third sensor electrode 343a and the third floating electrode 343b. Furthermore, as shown in FIG. 6 and FIG. 9, the third concave and convex structure portion 363 is positioned so that the position of the third concave and convex structure portion 363 in the first direction D1 overlaps with all of the floating electrodes 341b, 342b, and 343b of the beam portion 32.

As shown in FIGS. 7 to 9, each of the plurality of concave and convex structure portions 36 includes a plurality of first concave and convex parts 37 and a plurality of second concave and convex parts 38. Each of the plurality of first concave and convex parts 37 has a first concave 371 provided on the one surface 32c of the beam portion 32, and a first convex 372 provided on the opposite surface 32d of the beam portion 32 at a portion that overlaps with the first concave 371 on the opposite side of the directional axis direction Da. The first concave 371 and the first convex 372 each extend linearly in the second direction D2.

On the other hand, the second concave and convex part 38 has a shape obtained by inverting the first concave and convex part 37 in the directional axis direction Da. That is, each of the plurality of second concave and convex parts 38 has a second convex 381 provided on the one surface 32c of the beam portion 32, and a second concave 382 provided on the opposite surface 32d of the beam portion 32 at a portion that overlaps with the second convex 381 on the opposite side of the directional axis direction Da. The second convex 381 and the second concave 382 each extend linearly in the second direction D2.

In each of the plurality of concave and convex structure portions 36, the first concave and convex part 37 and the second concave and convex part 38 are positioned alternately in the first direction D1, and the first concave and convex part 37 and the second concave and convex part 38 adjacent to each other in the first direction D1 are continuously connected. That is, in the cross section perpendicular to the second direction D2, each of the plurality of concave and convex structure portions 36 has a wavy shape in which the first concave and convex part 37 and the second concave and convex part 38 are alternately and continuously connected. The wavy cross-sectional shape of the concave and convex structure portions 36 can be formed by, for example, etching.

Each of the plurality of concave and convex structure portions 36 is formed to have a uniform thickness tw in the cross section perpendicular to the second direction D2. Here, the uniformity of the thickness tw of the concave and convex structure portion 36 does not necessarily mean that the thickness tw is strictly constant, and the thickness tw is considered uniform if variations in the thickness tw are comparable to the variations caused by the presence or absence of the electrode layers 34. The thickness tw of the concave and convex structure portion 36 does not mean a dimension in a direction along the directional axis direction Da, but means a thickness in a direction following the wavy shape of the concave and convex structure portion 36.

For example, in the present embodiment, the plurality of piezoelectric layers 35 occupy most of the beam portion 32 of the vibration plate 3. The plurality of piezoelectric layers 35 are formed so that the total thickness of the plurality of piezoelectric layers 35 is uniform in the cross section perpendicular to the second direction D2.

For example, as shown in FIG. 7, in any of the plurality of concave and convex structure portions 36, each of a recess amount H1 of the first concave 371 from the one surface 32c of the beam portion 32 and a recess amount H2 of the second concave 382 from the opposite surface 32d is less than half a plate thickness tb of the beam portion 32 in the directional axis direction Da. Therefore, neither the first concave 371 nor the second concave 382 reaches the neutral axis Ln of the bending deformation of the beam portion 32.

The piezoelectric device 1 according to the present embodiment described above can provide the following advantageous effects. As shown in FIGS. 6 to 9, according to the present embodiment, the beam portion 32 of the vibration plate 3 includes the plurality of concave and convex structure portions 36, and each of the plurality of concave and convex structure portions 36 includes the plurality of first concave and convex parts 37 and the plurality of second concave and convex parts 38. Each of the first concave and convex parts 37 has the first concave 371 provided on the one surface 32c of the beam portion 32, and the first convex 372 provided on the opposite surface 32d of the beam portion 32 at the portion that overlaps with the first concave 371 on the opposite side of the directional axis direction Da. The first concave 371 and the first convex 372 each extend linearly in the second direction D2. On the other hand, each of the second concave and convex parts 38 has the second convex 381 provided on the one surface 32c of the beam portion 32, and the second concave 382 provided on the opposite surface 32d of the beam portion 32 at the portion that overlaps with the second convex 381 on the opposite side of the directional axis direction Da. The second convex 381 and the second concave 382 each extend linearly in the second direction D2.

When the beam portion 32 includes the concave and convex structure portions 36 as described above, a bending rigidity of the beam portion 32 against a deflection of the beam portion 32 that occurs in the transverse cross section perpendicular to the first direction D1 is increased compared to, for example, a case in which there is no concave and convex structure portions 36 and the entire beam portion 32 is flat. On the other hand, since the first concave 371, the second concave 382, the first convex 372, and the second convex 381 each extend linearly in the second direction D2, a bending rigidity of the beam portion 32 against a deflection of the beam portion 32 that occurs in the cross section perpendicular to the second direction D2 is not increased.

Therefore, while not hindering the vibration of the beam portion 32, the deflection of the beam portion 32 that occurs in the transverse cross section perpendicular to the first direction D1 can be restricted compared to, for example, a case in which there is no concave and convex structure portion and the entire beam portion is flat.

Furthermore, according to the present embodiment, the recess amount H1 of the first concave 371 from the one surface 32c of the beam portion 32 and the recess amount H2 of the second concave 382 from the opposite surface 32d are each less than half the plate thickness tb of the beam portion 32 in the directional axis direction Da. Therefore, neither the first concave 371 nor the second concave 382 reaches the neutral axis Ln of the bending deformation of the beam portion 32. In other words, the neutral axis Ln does not intersect either the first concave 371 or the second concave 382, and therefore passes through the concave and convex structure portion 36 without partially departing from the concave and convex structure portion 36.

Here, in vibrations involving bending deformation of the beam portion 32, tensile strain occurs on one side of the beam portion 32 on either side of the neutral axis Ln, and simultaneously compressive strain occurs on the other side. However, in the above-described configuration, both tensile strain and compressive strain occur simultaneously over the entire area of the concave and convex structure portion 36 in plan view. Therefore, it is possible to restrict a decrease in the sensitivity of the piezoelectric device 1 caused by providing the concave and convex structure portion 36.

Furthermore, according to the present embodiment, the first concave and convex structure portion 361 is disposed within the overlapping range of the beam portion 32 where the sensor electrode ranges W1, W2, W3 of the sensor electrodes 341a, 342a, 343a all overlap. Here, the occurrence of the transverse cross-sectional deflection of the beam portion 32 at the locations of the beam portion 32 where the first to third sensor electrodes 341a, 342a, 343a are positioned is what is most likely to lead to the decrease in the sensitivity of the piezoelectric device 1. Therefore, by arranging the first concave and convex structure portion 361 within the overlapping range, it is possible to effectively restrict the transverse cross-sectional deflection, which is likely to lead to the decrease in the sensitivity of the piezoelectric device 1.

Furthermore, according to the present embodiment, the second concave and convex structure portion 362 is positioned in the beam portion 32 between the third sensor electrode 343a and the third floating electrode 343b. Therefore, it is possible to arrange the second concave and convex structure portion 362 in the vicinity of the third sensor electrode 343a while avoiding design constraints imposed by the third sensor electrode 343a and the third floating electrode 343b, and to restrict the transverse cross-sectional deflection of the beam portion 32 that may occur at the location where the third sensor electrode 343a is positioned.

Furthermore, according to the present embodiment, each of the plurality of concave and convex structure portions 36 is formed to have the uniform thickness tw in the cross section perpendicular to the second direction D2. Therefore, it is possible to restrict the variation in the bending rigidity against the bending deformation of the beam portion 32 that occurs in the cross section perpendicular to the second direction D2 within the concave and convex structure portion 36.

### Second Embodiment

Next, a second embodiment will be described. The present embodiment is explained mainly with respect to points different from those of the first embodiment. In addition, explanations of the same or equivalent portions as those in the above embodiment is omitted or simplified. The same is also true for the description of the later-described embodiments.

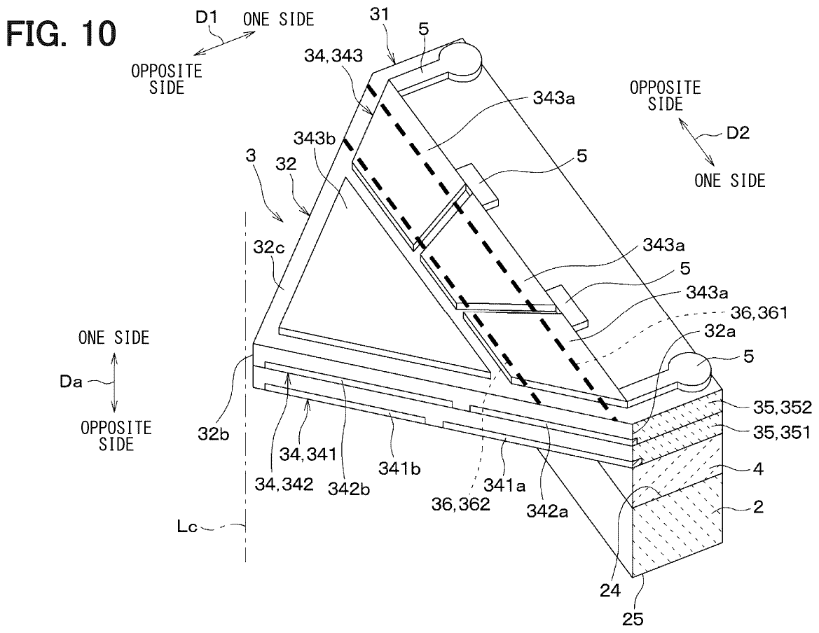

As shown in FIG. 10, in the present embodiment, the beam portion 32 of the vibration plate 3 includes two concave and convex structure portions 36. Therefore, the beam portion 32 of the present embodiment includes the first concave and convex structure portion 361 and the second concave and convex structure portion 362, but does not include a third concave and convex structure portion 363 (see FIG. 6), unlike the first embodiment.

Moreover, unlike the first embodiment, the second concave and convex structure portion 362 of the present embodiment is not positioned between the third sensor electrode 343a and the third floating electrode 343b. As shown in FIG. 3 and FIG. 10, the second concave and convex structure portion 362 of the present embodiment, like the first concave and convex structure portion 361, is positioned within the first sensor electrode range W1, the second sensor electrode range W2, and the third sensor electrode range W3 of the beam portion 32, which overlap each other.

In detail, all of the concave and convex structure portions 36 of the beam portion 32 are positioned only within the first sensor electrode range W1, the second sensor electrode range W2, and the third sensor electrode range W3 of the beam portion 32, which overlap each other. In other words, all of the concave and convex structure portions 36 of the beam portion 32 are positioned only within the overlapping range of the beam portion 32 where the sensor electrode ranges W1, W2, W3 of each of the sensor electrodes 341a, 342a, 343a all overlap. Since the second concave and convex structure portion 362 is positioned within the overlapping range, it has the same cross-sectional configuration in the cross section perpendicular to the second direction D2 as the first concave and convex structure portion 361 shown in FIG. 7.

According to the present embodiment, as shown in FIG. 3, the first sensor electrode area W1, the second sensor electrode area W2, and the third sensor electrode area W3 overlap each other. As shown in FIG. 3 and FIG. 10, all of the concave and convex structure portions 36 of the beam portion 32 are positioned only within the first sensor electrode range W1, the second sensor electrode range W2, and the third sensor electrode range W3 of the beam portion 32.

Therefore, by providing the concave and convex structure portions 36 at the locations of the sensor electrodes 341a, 342a, and 343a, where the occurrence of the transverse cross-sectional deflection of the beam portion 32 is most likely to lead to the decrease in the sensitivity, it is possible to effectively restrict the decrease in the sensitivity caused by the transverse cross-sectional deflection. On the other hand, since the concave and convex structure portion 36 is not provided at a location where the effect of restricting the decrease in the sensitivity caused by the transverse cross-sectional deflection is relatively weak, any constraints that may arise due to the provision of the concave and convex structure portion 36 can be alleviated. As a result, for example, it becomes easier to ensure the reliability of the piezoelectric device 1.

In addition, the first to third sensor electrode ranges W1, W2, W3 in which all of the concave and convex structure portions 36 are positioned are biased toward the one side in the first direction D1 of the beam portion 32, and the beam portion 32 is formed so as to widen in the second direction D2 toward the one side in the first direction D1. The wider the width of the beam portion 32 in the second direction D2, the more likely it is that the beam portion 32 will have a large transverse cross-sectional deflection. Therefore, the concave and convex structure portion 36 is concentrated in areas where the cross-sectional deflection is likely to occur significantly, which also makes it possible to effectively restrict the decrease in the sensitivity caused by the transverse cross-sectional deflection.

The present embodiment is similar to the first embodiment, except for the above described aspects. Thus, the present embodiment can achieve the advantages obtained by the configuration common to the first embodiment described above in a similar manner as in the first embodiment.

### Third Embodiment

Next, a third embodiment will be described. The present embodiment will be explained mainly with respect to portions different from those of the first embodiment.

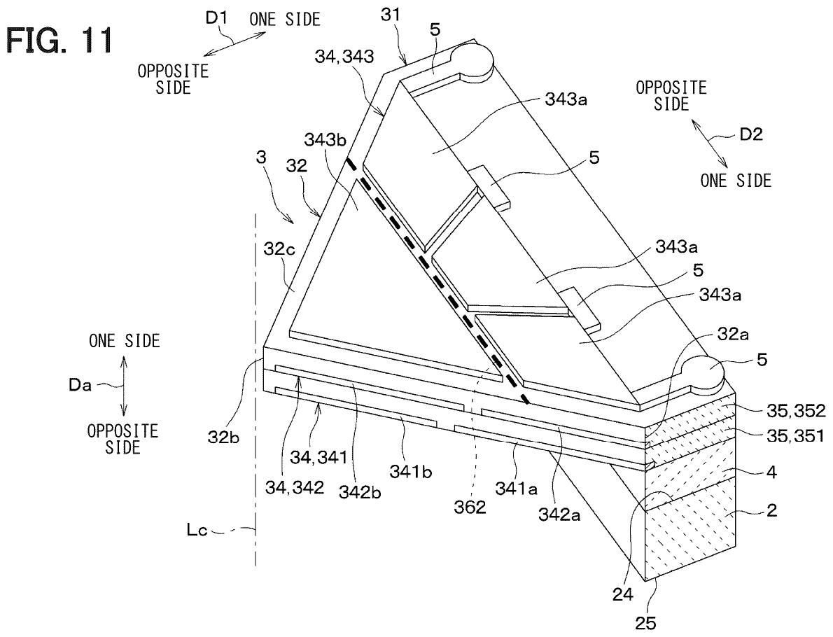

As shown in FIG. 11, in the present embodiment, the beam portion 32 of the vibration plate 3 includes the second concave and convex structure portion 362, but does not include the first concave and convex structure portion 361 and the third concave and convex structure portion 363 among the first to third concave and convex structure portions 361, 362, and 363 in FIG. 6. Therefore, in the following description of the present embodiment, the second concave and convex structure portion 362 will be simply referred to as the concave and convex structure portion 362.

According to the present embodiment, the concave and convex structure portion 362 of the beam portion 32 is disposed only between the third sensor electrode 343a and the third floating electrode 343b of the beam portion 32. That is, the concave and convex structure portion 362 is disposed at a position away from both the third sensor electrode 343a and the third floating electrode 343b.

Therefore, when designing the concave and convex structure portion 362, there is no need to be concerned about design constraints imposed by the third sensor electrode 343a and the third floating electrode 343b, so that the design freedom regarding the vibration plate 3 can be increased. Furthermore, since the concave and convex structure portion 362 is disposed in the vicinity of the third sensor electrode 343a, it is possible to obtain the effect of restricting the transverse cross-sectional deflection of the beam portion 32 that may occur at the location where the third sensor electrode 343a is disposed.

Aside from the above described aspects, the present embodiment is the same as the first embodiment. Thus, in the present embodiment, the same effects as the first embodiment described above can be obtained in the same manner as in the first embodiment.

### Fourth Embodiment

Next, a fourth embodiment will be described. The present embodiment will be explained mainly with respect to portions different from those of the third embodiment.

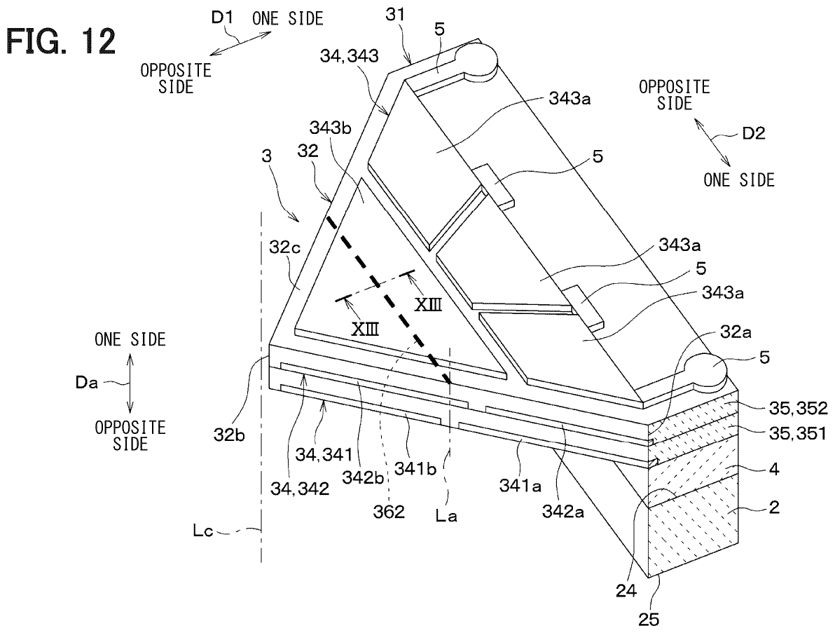

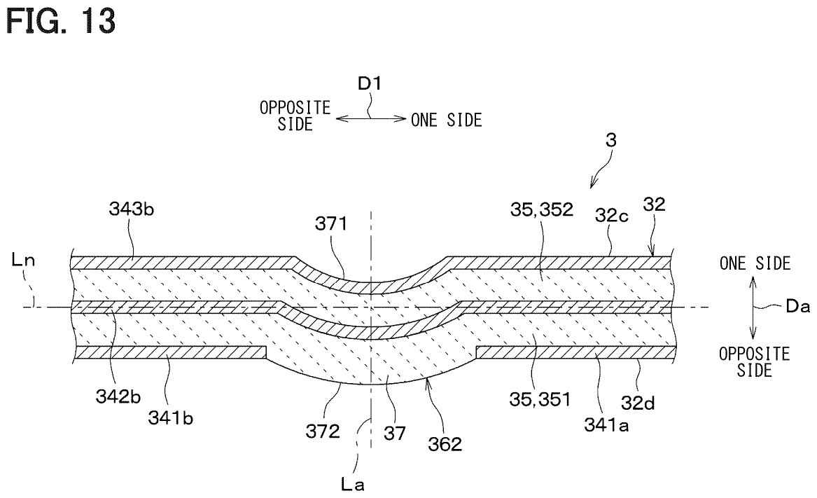

As shown in FIG. 12 and FIG. 13, the concave and convex structure portion 362 of the present embodiment is positioned in the beam portion 32 between the first sensor electrode 341a and the first floating electrode 341b, rather than between the third sensor electrode 343a and the third floating electrode 343b. That is, the concave and convex structure portion 362 in the present embodiment is positioned in the beam portion 32 only between the first sensor electrode 341a and the first floating electrode 341b. In FIG. 12 and FIG. 13, a dotted line La is drawn to clearly show the arrangement of the concave and convex structure portion 362, and the dotted line La represents a center position between the first sensor electrode 341a and the first floating electrode 341b in the first direction D1.

Moreover, the concave and convex structure portion 362 of the present embodiment does not have the second concave and convex part 38 (see FIG. 8) and is composed of the first concave and convex part 37. More specifically, in the present embodiment, the concave and convex structure portion 362 is composed of one first concave and convex part 37.

Since the concave and convex structure portion 362 is configured as described above, it is possible to form the concave and convex structure portion 362 by performing over-etching to separate the first sensor electrode 341a and the first floating electrode 341b during the manufacture of the piezoelectric device 1. Therefore, it is possible to form the concave and convex structure portion 362 while restricting an increase in the number of manufacturing processes that would be required to form the concave and convex structure portion 362.

Aside from the above described aspects, the present embodiment is the same as the third embodiment. Thus, the present embodiment can achieve the advantages obtained by the configuration common to the third embodiment described above in a similar manner as in the third embodiment.

### Other Embodiments

In each of the above-described embodiments, the piezoelectric device 1 is adopted for the microphone that converts sound waves or ultrasonic waves into electric signals, but this is just one example. Conversely, the piezoelectric device 1 may be adopted for a speaker that converts electrical signals into sound waves or ultrasonic waves.

In each of the above-described embodiments, for example, as shown in FIG. 3, the vibration plate 3 includes three electrode layers 34 and two piezoelectric layers 35, but this is just one example. The electrode layers 34 may be provided in four or more layers, and the piezoelectric layers 35 may be provided in three or more layers.

In the first embodiment, as shown in FIGS. 7 to 9, each of the concave and convex structure portions 36 has the plurality of first concave and convex parts 37 and the plurality of second concave and convex parts 38, but this is just one example. For example, each of the concave and convex structure portions 36 may have one first concave and convex part 37 and one second concave and convex part 38. In another example, each of the concave and convex structure portions 36 may have only one of the first concave and convex part 37 and the second concave and convex part 38, and it is acceptable that each of the concave and convex structure portions 36 does not have the other.

In the first embodiment, as shown in FIGS. 7 to 9, the wavy shape of each of the concave and convex structure portions 36 appearing in the cross section perpendicular to the second direction D2 is smoothly curved and wavy, but this is just one example. For example, the wavy shape of each of the concave and convex structure portions 36 appearing in the cross section perpendicular to the second direction D2 may be wavy while bending to sharpen the first convex 372 and the second convex 381.

In each of the above-described embodiments, as shown in FIG. 3, the separation portion between the first sensor electrode 341a and the first floating electrode 341b, the separation portion between the second sensor electrode 342a and the second floating electrode 342b, and the separation portion between the third sensor electrode 343a and the third floating electrode 343b are shifted with respect to each other in the first direction D1. However, this is merely an example, and the positions of the separation portions in the first direction D1 may be aligned with each other.

In the above-described embodiments, as shown in FIG. 1 and FIG. 2, the beam portion 32 of the vibration plate 3 has a triangular shape in plan view, but is not limited to this example. For example, the shape of the beam portion 32 in plan view may be a rectangular shape, a trapezoidal shape, or various other shapes.

In each of the above-described embodiments, the piezoelectric device 1 has four vibration plates 3, but this is just an example. For example, the piezoelectric device 1 may have one, two, or three vibration plates 3, or may have five or more vibration plates 3.

The base substrate 2 may have various shapes. For example, the base substrate 2 may have a shape surrounding the directional axis Lc, such as a cylindrical shape, an elliptical cylindrical shape, a triangular cylindrical shape, a pentagonal cylindrical shape, a hexagonal cylindrical shape, or an octagonal cylindrical shape. Alternatively, the base substrate 2 may have a shape surrounding the directional axis Lc, such as a circular ring, an elliptical ring, a triangular ring, a pentagonal ring, a hexagonal ring, or an octagonal ring.

In each of the above-described embodiments, the vibration plate 3 is fixed to the one end surface 24 of the base substrate 2, but the present disclosure is not limited to this example. For example, an outer edge of the vibration plate 3, which is provided at the one end in the first direction D1 and constitutes the fixed end 32a, can be fixed by a groove, an adhesive layer, or the like, provided on the inner wall surface 22 of the base substrate 2. That is, the fixed portion 31 of the vibration plate 3, which is not subject to flexural vibration, may be omitted. In this case, the entire vibration plate 3 constitutes the beam portion 32 that is subjected to flexural vibration.

In each of the above-described embodiments, the oxide film 4 may be omitted. Alternatively, instead of the oxide film 4, a film for improving a bonding state between the base substrate 2 and the vibration plate 3 may be provided. There are no particular limitations on the materials that constitute each component. In the present disclosure, the terms “film” and “layer” are interchangeable.

In the above description, a plurality of elements formed integrally with each other with no seam may be formed by bonding separate members together. Similarly, a plurality of elements formed by bonding separate members together may be formed integrally with each other with no seam. Furthermore, a plurality of components that are made of the same material in the above description may be made of different materials. Similarly, a plurality of elements made of different materials in the above description may be made of the same material.

The present disclosure is not limited to the above-described embodiments, and can be implemented in various modifications. The constituent element(s) of each of the above-described embodiments is/are not necessarily essential unless it is specifically stated as essential in the above-described embodiments, or unless obviously essential in principle.

A quantity, a value, an amount, a range, or the like referred to in the description of the embodiments described above is not necessarily limited to the specific value, amount, range or the like unless specifically described as essential or understood as essential in principle. Furthermore, a material, a shape, a positional relationship, or the like, if specified in the above-described embodiments, is not necessarily limited to the specific material, shape, positional relationship, or the like unless it is specifically stated that the material, shape, positional relationship, or the like is necessarily the specific material, shape, positional relationship, or the like, or unless the material, shape, positional relationship, or the like is obviously necessary to be the specific material, shape, positional relationship, or the like in principle.

What is claimed is:

1. A piezoelectric device to be adopted for a microphone or a speaker, comprising:
a beam portion including a piezoelectric layer made of a piezoelectric material, having a plate shape perpendicular to an axial direction of a directional axis of the piezoelectric device, and having a fixed end provided on one side of the beam portion in a first direction perpendicular to the axial direction, a free end provided on an opposite side of the beam portion in the first direction, one surface provided on one side of the beam portion in the axial direction, and an opposite surface provided on an opposite side of the beam portion in the axial direction, the beam portion configured as a cantilever beam in which the free end is capable of reciprocating displacement in the axial direction with respect to the fixed end; and
a support portion to which the fixed end of the beam portion is fixed and which supports the fixed end, wherein
the beam portion includes a concave and convex structure portion having at least one of a first concave and convex part and a second concave and convex part,
the first concave and convex part has a first concave provided on the one surface and extending linearly in a second direction perpendicular to the axial direction and the first direction, and a first convex provided on the opposite surface at a portion overlapping the first concave on the opposite side in the axial direction and extending linearly in the second direction, and
the second concave and convex part has a second convex provided on the one surface and extending linearly in the second direction, and a second concave provided on the opposite surface at a portion overlapping the second convex on the opposite side in the axial direction and extending linearly in the second direction.

2. The piezoelectric device according to claim 1, wherein
each of a recess amount of the first concave from the one surface and a recess amount of the second concave from the opposite surface is less than half a plate thickness of the beam portion in the axial direction.

3. The piezoelectric device according to claim 1, wherein
the beam portion includes a plurality of sensor electrodes laminated in different layers on the piezoelectric layer and electrically connected to a wiring leading to an outside of the beam portion, and
the concave and convex structure portion is positioned within an overlapping range of the beam portion in which ranges occupied by the plurality of sensor electrodes in the first direction all overlap with each other.

4. The piezoelectric device according to claim 1, wherein
a width of the beam portion in the second direction increases toward the one side in the first direction,
the beam portion includes an electrode layer made of a conductive material and laminated on the piezoelectric layer,
the electrode layer includes a sensor electrode electrically connected to a wiring leading to an outside of the beam portion, and a floating electrode spaced apart from the wiring and positioned on the opposite side of the sensor electrode in the first direction, and
the concave and convex structure portion is positioned only within a range of the beam portion that is occupied by the sensor electrode in the first direction.

5. The piezoelectric device according to claim 1, wherein
a width of the beam portion in the second direction increases toward the one side in the first direction,
the beam portion includes an electrode layer made of a conductive material and laminated on the piezoelectric layer,
the electrode layer includes a sensor electrode electrically connected to a wiring leading to an outside of the beam portion, and a floating electrode spaced apart from the wiring and positioned on the opposite side of the sensor electrode in the first direction, and
the concave and convex structure portion is positioned in the beam portion between the sensor electrode and the floating electrode.

6. The piezoelectric device according to claim 1, wherein
the piezoelectric layer is provided in two or more layers,
the beam portion includes an electrode layer made of a conductive material and provided in three or more layers, and
the electrode layer and the piezoelectric layer are alternately laminated in the axial direction.

7. The piezoelectric device according to claim 1, wherein
the support portion is disposed on the opposite side in the axial direction with respect to the beam portion,
the beam portion includes an electrode layer made of a conductive material and laminated on the piezoelectric layer to form the opposite surface of the beam portion,
the electrode layer includes a sensor electrode electrically connected to a wiring leading to an outside of the beam portion, and a floating electrode spaced apart from the wiring and positioned on the opposite side of the sensor electrode in the first direction,
the concave and convex structure portion has the first concave and convex part and does not have the second concave and convex part, and
the concave and convex structure portion is positioned in the beam portion between the sensor electrode and the floating electrode.

8. The piezoelectric device according to claim 1, wherein
the concave and convex structure portion has a uniform thickness in a cross section perpendicular to the second direction.

9. The piezoelectric device according to claim 1, wherein
the piezoelectric material is one selected from a group consisting of aluminum nitride, scandium aluminum nitride, zinc oxide, lead zirconate titanate, potassium lithium niobate, potassium sodium niobate, and barium titanate.
